(19) United States
(12) Patent Application Publication
(10) Pub. No.: US 2008/0305646 A1
(43) Pub. Date: Dec. 11, 2008

(54) Atomic layer deposition

(75) Inventors: Chen-Hua Yu, Hsinchu (TW); Liang-Gi Yao, Hsinchu (TW)

Correspondence Address: BIRCH, STEWART, KOLASCH & BIRCH, LLP, P.O. BOX 747, FALLS CHURCH, VA, 22040-0747, US

(73) Assignee: TAIWAN SEMICONDUCTOR MANUFACTURING CO., LTD.

(21) Appl. No.: 11/808,388

(22) Filed: Jun. 8, 2007

(51) Int. Cl. H01L 21/31

(52) U.S. Cl. 438/785; 257/E21.24

(57) ABSTRACT

An atomic layer deposition with hydroxylation pre-treatment is provided. The atomic layer deposition comprises the steps of (a) performing a hydroxylation pre-treatment on a silicon substrate to create a predetermined number of hydroxyl groups thereon; (b) performing a precursor pulse on the pre-treated silicon substrate, wherein the precursor react with the hydroxyl groups, forming a layer; (c) purging the silicon substrate with an inert carrier gas; (d) performing a water pulse on the layer sufficiently so as to create a predetermined number of hydroxyl groups thereon; (e) purging the layer with the inert carrier gas; and (f) repeating steps (b)˜(e) until the atomic layer deposition is completed. Each layer overlying the silicon substrate has a minimum of 70 percent surface hydroxyl groups.

### BACKGROUND OF THE INVENTION

1. Field of the Invention

The present invention relates to atomic layer deposition.

2. Description of the Related Art

Atomic layer deposition (ALD), for example, disclosed in U.S. Pat. No. 6,764,927, is a well known deposition technique in the semiconductor industry. ALD employs a precursor and a reactive gas to form an ALD layer on a substrate in a chamber.

The deposited ALD layer, however, typically suffers from issues such as pinholes, or low density, leading to leakage current when applied in PMOS or NMOS transistors.

Accordingly, a denser ALD layer capable of solving the described issues is desirable.

### BRIEF SUMMARY OF THE INVENTION

An embodiment showing an atomic layer deposition (ALD) is disclosed, comprising the steps of (a) performing a hydroxylation pre-treatment on a silicon substrate to create a predetermined number of hydroxyl groups thereon; (b) performing a precursor pulse on the pre-treated silicon substrate, wherein the precursor reacts with the hydroxyl groups, forming a layer; (c) purging the silicon substrate with an inert carrier gas; (d) sufficiently exposing the layer to a water pulse to create a predetermined number of hydroxyl groups thereon; (e) purging the layer with the inert carrier gas; and (f) repeat the steps (b)˜(e) until the atomic layer deposition is completed. Furthermore, each layer overlying the silicon substrate has a minimum of 70 percent surface hydroxyl groups

Another embodiment showing an atomic layer deposition is disclosed, comprising: (a) performing a hydroxylation pre-treatment on a silicon substrate to create hydroxyl groups having a surface coverage of 30% thereon; (b) performing a precursor pulse on the pre-treated silicon substrate, wherein the precursor reacts with the hydroxyl groups, forming a layer; (c) purging the silicon substrate with an inert carrier gas; (d) sufficiently exposing the layer to a water pulse so that the layer has a minimum of 70 percent surface hydroxyl groups;(e) purging the layer with the inert carrier gas; and (f) repeating steps (b)˜(e) until the atomic layer deposition is completed.

Another embodiment showing an atomic layer deposition for forming a gate dielectric layer is disclosed, comprising: providing a semiconductor substrate; treating the semiconductor substrate with a wetting material to provide a wettable semiconductor substrate having a minimum of 60 percent surface hydroxyl groups; forming upon the wettable semiconductor substrate a first reactant material layer; and treating the first reactant material layer with a second reactant material to form a gate dielectric layer having a minimum of 70 percent surface hydroxyl groups upon the wettable semiconductor substrate.

According to the described embodiments, a denser and thinner ALD layer applicable to PMOS or NMOS transistors can be formed, thus eliminating issues such as leakage current therein.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows a flowchart of a comparative example of atomic layer deposition.

FIG. 2 shows a flowchart of embodiments of atomic layer deposition.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

### COMPARATIVE EXAMPLE

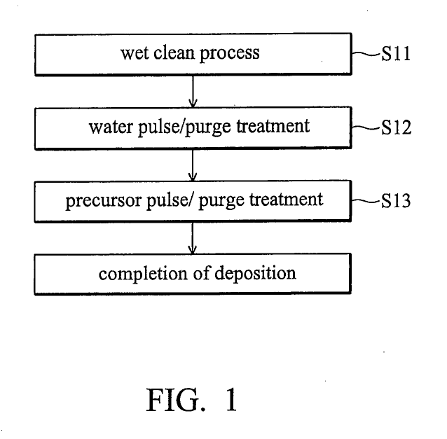

FIG. 1 shows a flowchart of atomic layer deposition for a comparative example.

As shown in FIG. 1, in step S11, a silicon substrate is subjected to a wet cleaning process in previous step process. The wet cleaning process may use a standard clean 1 (SC1) solution (NH₄OH/H₂O₂/H₂O), standard clean 2 (SC2) solution (HCl/H₂O₂/H₂O) and HF solution sequentially, or use standard clean 1 (SC1) solution (NH₄OH/H₂O₂/H₂O), standard clean 2 (SC2) solution (HCl/H₂O₂/H₂O) and HF vapor sequentially, or use HF vapor, standard clean 1 (SC1) solution (NH₄OH/H₂O₂/H₂O) and standard clean 2 (SC2) solution (HCl/H₂O₂/H₂O) sequentially, or use HF solution, standard clean 1 (SC1) solution (NH₄OH/H₂O₂/H₂O) and standard clean 2 (SC2) solution (HCl/H₂O₂/H₂O) sequentially, or use other dilute ozone solution in final cleaning step.

As shown in FIG. 1, in step S12, two water pulse cycles i.e. hydroxylation pre-treatment and purge treatment proceeds, thus hydroxyl groups having a surface coverage of 60% are generated over the silicon substrate.

As shown in FIG. 1, in step S13, a precursor pulse and a purge treatment is then performed. Finally, a layer (also an atomic layer deposition layer) of a desired thickness e.g. between 30 and 100 angstroms is formed.

As described, the comparative example is characterized in that hydroxyl groups having a surface coverage of 60% are generated over the silicon substrate. This facilitates deposition i.e. atomic layer deposition of the precursor; however, the density of the layer is inadequate.

To obtain a denser ALD layer, some embodiments of the invention provide methods for depositing each layer overlying the silicon substrate with a surface coverage of greater than 70%. Furthermore, the deposited layer of these embodiments is denser and thinner (thinner film could be formed using fewer cycle numbers with better leakage) than that of the comparative example.

### First Embodiment

In this embodiment the water vapor utilized in each water pulse is increased to a predetermined temperature for obtaining a high surface coverage of each layer overlying the silicon substrate.

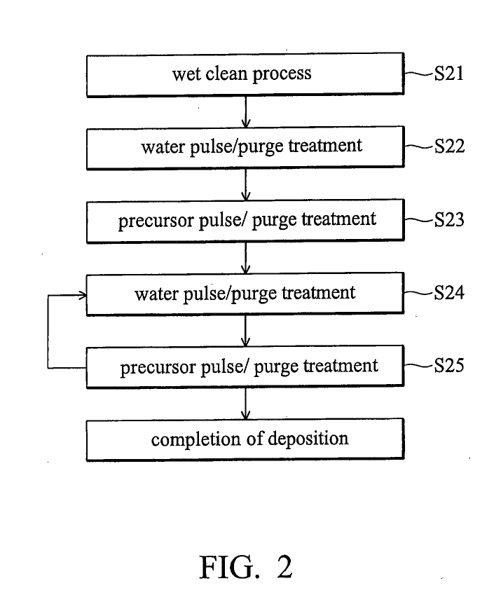

As shown in FIG. 2, steps S21 and S22 are identical to steps S11 and S12, thus further description thereof is omitted here.

In step S23, a precursor such as HfCl₄ is introduced into the chamber, and reacts with the hydroxyl groups (—OH) over the pre-treated silicon substrate, thus forming a first HfO₂ layer (containing chlorine atoms thereon). Subsequent to completion of the reaction, an inert carrier gas such as nitrogen is then used to purge the unreacted HfCl₄. To complete the reaction, the duration for which a sufficient number of HfCl₄ is provided is extended.

To achieve a high surface coverage of a second HfO₂ layer over the first HfO₂ layer (containing chlorine atoms thereon), in step S24, a water pulse in which the water vapor is increased to a predetermined temperature is performed on the first HfO₂ layer. The higher the water temperature increase, the more the water vapor can be generated. More water vapor means that more chlorine atoms over the first HfO₂ layer can be replaced with the hydroxyl groups (—OH) of the generated water vapor. The surface coverage of the hydroxyl groups (—OH) over the first HfO₂ layer can be greater than 70% here. After hydroxylation of the first HfO₂ layer, an inert carrier gas such as nitrogen is then used to purge the remaining water vapor and the side products.

In step S25, a second HfO₂ layer can be obtained by introducing a precursor such as HfCl₄ into the chamber again, and an inert carrier gas such as nitrogen is then used to purge the unreacted HfCl₄. The subsequent HfO₂ layer (e.g. third HfO₂ layer, fourth HfO₂ layer . . . etc.) can be formed in this way i.e. repetition of steps S24 and S25 over ten times. A resultant HfO₂ layer capable of serving as a gate dielectric layer is therefore obtained.

### Second Embodiment

This embodiment features that the water vapor utilized in each water pulse is increased to a predetermined temperature for obtaining a high surface coverage of each layer overlying the silicon substrate. This embodiment will be described with reference to FIG. 2 again.

As shown in FIG. 2, steps S21 to S23 are identical to those of the first embodiment, thus further description thereof is omitted here.

In step S24, a water pulse is performed on the first HfO₂ layer for an extended period to achieve a high surface coverage of a second HfO₂ layer over the first HfO₂ layer (containing chlorine atoms). Sufficiently extending the period of the water pulse can generate more water vapor. Utilizing more water vapor can replace more of chlorine atoms over the first HfO₂ layer with the hydroxyl groups (—OH) generated from water vapor. The surface coverage of the hydroxyl groups (—OH) over the first HfO₂ layer can be greater than 70% here. After hydroxylation of the first HfO₂ layer, an inert carrier gas such as nitrogen, helium etc. is then used to purge the remaining water vapor and the side products.

In step S25, a second HfO₂ layer can be obtained by again introducing a precursor such as HfCl₄ into the chamber, and an inert carrier gas such as nitrogen is then used to purge the unreacted HfCl₄. The subsequent HfO₂ layers (e.g. third HfO₂ layer, fourth HfO₂ layer . . . etc.) can be formed by repeating steps S24 and S25 ten times. A resultant HfO₂ layer capable of serving as a gate dielectric layer is therefore obtained.

According to the first and second embodiments, a denser ALD layer applicable for PMOS or NMOS transistors can be formed, thus eliminating issues such as leakage current therein.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An atomic layer deposition, comprising:
(a) performing a hydroxylation pre-treatment on a silicon substrate to create a predetermined number of hydroxyl groups thereon;
(b) performing a precursor pulse on the pre-treated silicon substrate, wherein the precursor reacts with the hydroxyl groups, forming a layer;
(c) purging the silicon substrate with an inert carrier gas;
(d) sufficiently exposing the layer to a water pulse to create a predetermined number of hydroxyl groups thereon;
(e) purging the layer with the inert carrier gas; and
(f) repeating steps (b) to (e) until the atomic layer deposition is completed;
wherein each layer overlying the silicon substrate has a minimum of 70 percent surface hydroxyl groups.

2. The atomic layer deposition as claimed in claim 1, wherein the precursor is metal precursor, comprising HfCl₄ and other metal precursors.

3. The atomic layer deposition as claimed in claim 2, wherein the layer is composed of HfO₂ and other rare earth oxides.

4. The atomic layer deposition as claimed in claim 1, wherein water vapor is employed in step (d), and a temperature thereof is increased to facilitate creation of hydroxyl groups overlying the layer.

5. The atomic layer deposition as claimed in claim 1, wherein a duration of the water pulse operation is increased to facilitate creation of hydroxyl groups overlying the layer.

6. The atomic layer deposition as claimed in claim 1, wherein a duration of the precursor pulse operation is increased to completely react the precursor with the hydroxyl groups overlying the layer.

7. The atomic layer deposition as claimed in claim 1, wherein steps (b) to (e) comprise a cycle that is repeated ten times or above.

8. The atomic layer deposition as claimed in claim 1, wherein steps (a) to (e) proceed in order in an atomic layer deposition chamber.

9. The atomic layer deposition as claimed in claim 1, wherein the inert carrier gas comprises nitrogen or other inert gases.

10. An atomic layer deposition, comprising:
(a) performing a hydroxylation pre-treatment on a silicon substrate to create a hydroxyl groups having a surface coverage of 60% thereon;
(b) performing a precursor pulse on the pre-treated silicon substrate, wherein the precursor reacts with the hydroxyl groups, forming a layer;
(c) purging the silicon substrate with an inert carrier gas;
(d) sufficiently exposing the layer to a water pulse so that the layer has a minimum of 70 percent surface hydroxyl groups;
(e) purging the layer with the inert carrier gas; and
(f) repeating steps (b)˜(e) until the atomic layer deposition is completed;

11. The atomic layer deposition as claimed in claim 10, wherein the precursor is metal precursor, comprising HfCl₄ and other metal precursors.

12. The atomic layer deposition as claimed in claim 11, wherein the layer is composed of HfO₂ and other rare earth oxides.

13. The atomic layer deposition as claimed in claim 10, wherein water vapor is employed in step (d), and a temperature thereof is increased to facilitate creation of hydroxyl groups overlying the layer.

14. The atomic layer deposition as claimed in claim 10, wherein a duration of the water pulse operation is increased to facilitate creation of hydroxyl groups overlying the layer.

15. The atomic layer deposition as claimed in claim 10, wherein a duration of the precursor pulse operation is increased to completely react the precursor with the hydroxyl groups overlying the layer.

16. The atomic layer deposition as claimed in claim 10, wherein steps (b) to (e) comprise a cycle that is repeated ten times or above.

17. The atomic layer deposition as claimed in claim 10, wherein steps (a) to (e) proceed in order in an atomic layer deposition chamber.

18. The atomic layer deposition as claimed in claim 10, wherein the inert carrier gas comprises nitrogen or other inert gases.

19. An atomic layer deposition for forming a gate dielectric layer, comprising:
providing a semiconductor substrate;
treating the semiconductor substrate with a wetting material to provide a wettable semiconductor substrate having a minimum of 60 percent surface hydroxyl groups;
forming upon the wettable semiconductor substrate a first reactant material layer; and
treating the first reactant material layer with a second reactant material to form a gate dielectric layer having a minimum of 70 percent surface hydroxyl groups upon the wettable semiconductor substrate.

20. The atomic layer deposition as claimed in claim 19, wherein the wetting material is moisture.
